(19) United States
(12) Patent Application Publication
(10) Pub. No.: US 2003/0124824 A1
(43) Pub. Date: Jul. 3, 2003

(54) High yield and high speed CMOS process

(76) Inventors: Manoj Mehrotra, Plano, TX (US); Gary Widder, Plano, TX (US); Mark Rodder, University Park, TX (US)

Correspondence Address: TEXAS INSTRUMENTS INCORPORATED, P O BOX 655474, M/S 3999, DALLAS, TX, 75265

(21) Appl. No.: 10/145,421

(22) Filed: May 14, 2002

Related U.S. Application Data
(60) Provisional application No. 60/344,515, filed on Dec. 28, 2001.

(51) Int. Cl. H01L 21/8238; H01L 21/336; H01L 21/3205; H01L 21/4763

(52) U.S. Cl. 438/585; 438/301; 438/919

(57) ABSTRACT

A process (10) for the production of a transistor device with reduced gate depletion is disclosed. The system includes providing a semiconductor substrate, forming a gate dielectric on an active area on the upper surface portion of the substrate and depositing a gate layer on top of the gate oxide. Next, the gate is implanted (12) with Boron and the N-doped regions of gate are patterned (14) and implanted (16).

This application claims priority from Provisional Application Serial No. 60/344,515, filed on Dec. 28, 2001.

### TECHNICAL FIELD OF THE INVENTION

The invention relates in general to the field of fabrication of semiconductor devices and, more particularly, to the fabrication of CMOS devices using an implant method that reduces gate depletion and gate profile variation for NMOS and PMOS gates.

### BACKGROUND OF THE INVENTION

In the process of manufacturing CMOS devices, numerous masking and etching steps are required to fabricate the electronic devices on the chip substrate. A conventional CMOS process involves polysilicon deposition followed by an N-polysilicon implant for NMOS and no implant for PMOS. Next, a polysilicon dopant anneal is conducted prior to polysilicon gate etch. The presence of dopants in N-polysilicon (doped polysilicon) over NMOS and no doping in polysilicon over PMOS (undoped polysilicon) results in different gate profiles for NMOS and PMOS. This difference in doping leads to gate profile and critical dimension (CD) control problems for CMOS.

One problem involves shallow trench isolation (STI) processes. The step height present in conventional CMOS process results in thicker polysilicon over active regions for narrow width transistors. Differences in polysilicon height causes depletion problems, especially for PMOS, since P-polysilicon is conventionally doped only at PSD and annealed with fast ramp rate rapid thermal anneal (RTA) (i.e., low thermal budget) to activate the dopants. This anneal step is not sufficient to drive and activate the dopants down for thicker polysilicon (narrow width transistors).

Therefore a need exists for a process that reduces gate depletion for NMOS and PMOS gates, producing more consistent doping and gate profiles, thereby reducing processing costs and improving the yield of the process. More particularly, what is needed is a system that reduces PMOS gate depletion without the addition of a masking step.

### SUMMARY OF THE INVENTION

The present invention provides a system for reducing gate depletion for NMOS and PMOS gates. The present invention provides an additional maskless P-polysilicon implant (e.g., Boron), followed by conventional patterned N-polysilicon implant (e.g., Phosphorous). The dose of Phosphorous implant may be increased/adjusted to compensate for the present of P-polysilicon implant over NMOS. Next, the polysilicon is etched directly without activating the dopants in N and P-polysilicon. Since the dopants are not activated, the N and P poly behave similarly during etch in terms of etch rate. Once the etch step is completed, the dopants may then be activated by a furnace anneal (700 C-1100 C). The furnace anneal ensures that the Boron is driven down the thicker polysilicon over narrow moat widths and achieves the necessary activation needed for good inversion capacitance for higher drive current.

More particularly, the present invention provides a system for the production of, e.g., a MOS transistor device having an integrated circuit, that begins by providing a polysilicon layer that is deposited on top of the gate dielectric (e.g., an oxide layer). A maskless Boron implant is made into the polysilicon. Following the implant, the N-doped polysilicon region is patterned. Next, Phosphorous is implanted into the N-doped polysilicon and the gate is patterned and etched.

### BRIEF DESCRIPTION OF THE DRAWINGS

For a more complete understanding of the features and advantages of the present invention, reference is now made to the detailed description of the invention along with the accompanying FIGURES in which corresponding numerals in the different FIGURES refer to corresponding parts and in which:

FIG. 1 is a flow chart depicting a process according to the present invention.

### DETAILED DESCRIPTION OF THE INVENTION

While the making and using of various embodiments of the present invention are discussed in detail below, it should be appreciated that the present invention provides many applicable inventive concepts that may be embodied in a wide variety of specific contexts. The specific embodiments discussed herein are merely illustrative of specific ways to make and use the invention and are not to delimit the scope of the invention.

The present invention recognizes that conventional CMOS processes using polysilicon deposition and N-doped polysilicon implant for NMOS, and no implant for PMOS, followed by polysilicon dopant anneal and polysilicon gate etch, result in differential depletion of the dopants and etch rates that affect gate performance, profile and CD control. The presence of dopants in N-doped polysilicon (doped polysilicon) over NMOS, and no doping in polysilicon over PMOS (undoped polysilicon), results in different gate profiles for NMOS and PMOS because the doped and undoped polysilicon lead to different depletion and gate profiles. In particular, doped polysilicon etches at a faster rate, but if the dopants are not activated, the difference in etch rate between doped and undoped regions is reduced.

Differences in doped and undoped polysilicon lead to different gate profiles and different gate CD's for a given CMOS device because of the variations in etch; that is, caused by the main etch or overetch. It is difficult to optimize both depletion of the dopants and the gate etch process to achieve desired gate profile (notch/foot), which is becoming increasingly critical for present and future technologies.

ULSI devices using STI step height present in conventional CMOS processes have polysilicon thickness variations (thicker polysilicon for larger step height and narrow width transistors), which cause polysilicon depletion. STI step height results in polysilicon depletion problems, especially for PMOS, since P-doped polysilicon is conventionally doped only at P-S/D and annealed with fast ramp rate rapid thermal anneal (RTA) (low thermal budget) to activate the dopants. Low budget thermal anneals are not sufficient to drive and activate the dopants down for thicker polysilicon (narrow width transistors).

For narrow width transistors, polysilicon height is significantly larger than for wide width transistors due to, e.g., STI step height. Narrow width transistors have polysilicon depletion problems in the PMOS region because it is doped only at S/D, and annealed with only the S/D spike, which is insufficient to drive the dopants to the poly/gate-oxide interface. Polysilicon depletion results in poor PMOS drive current, and higher beta ratio (Idn/Idp), resulting in yield loss.

Furthermore, all process flows requires a number of masking levels to produce the device. Each masking level and processing step increases the cost of production in terms of the individual process steps, and also in terms of yield loss due to process errors, processing time and the complexity of the process. The present invention may be used in conjunction with standard STI processing. STI processing allows isolation for sub 0.25 micrometer CMOS device features. The shallow trench isolation process uses a resist or a dielectric as a mask to etch trenches in silicon (trench depths usually being ˜<0.5 um for present technologies). A thin liner dielectric is then grown (on sidewall and top) followed by filling the trenches with dielectric (oxide). The wafers are then chemically-mechanically polished (CMP) to achieve planar surfaces prior to commencing the threshold adjust pattern and implants. A basic STI process for use with the present invention may be based on, e.g., A. Chatterjee, et. al., J. Vacuum Science Tech., Vol. 15, 1997, pp 1936-1942, relevant portions incorporated herein by reference. Following the STI process the Vt/Well is patterned and implanted, which is followed by gate oxidation and polysilicon gate deposition.

The present invention provides a CMOS process that reduces substantially the control problems with gate profile and critical dimension. In one embodiment, the present invention provides process steps for the production of an integrated circuit device, including the following steps: (1) providing a semiconductor substrate; (2) patterning a field oxide to define at least one active area on an upper surface portion of the substrate; (3) forming a gate oxide layer on an active area on the upper surface portion of the substrate; (4) forming a polysilicon gate layer on top of the gate oxide; (5) performing a Boron implant; (6) N-polysilicon gate patterning; and (7) N-polysilicon implant.

Summarizing, in one embodiment, the process of the invention includes the following fabrication steps in a simplified CMOS process:

| | |
|---|---|
| 1. | Polysilicon Deposition |
| 2. | Boron Implant |
| 3. | N-doped polysilicon pattern |
| 4. | Phosphorous N-doped polysilicon Implant (+ |
| | Boron compensation) |
| 5. | Gate Pattern |
| 6. | Gate Etch |
| 7. | (Optional Gate Anneal) |
| 8. | (Optional Gate ECD) |

The present invention uses a maskless P-doped polysilicon implant (e.g., Boron), followed by conventional patterned N-doped polysilicon implant (e.g., Phosphorous). The dose of N-doped polysilicon implant may be increased/adjusted to compensate for the presence of P-doped polysilicon implant over NMOS. These steps are followed by etching directly the polysilicon without activating the dopants in N and P polysilicon. Since the dopants are not activated, the N and P polysilicon behave similarly during processing (breakthrough, main etch and over etch) in terms of etch rate and final polysilicon gate profile. Once the gate etch is completed the dopants may then activated by a furnace anneal (700-1100 Celsius), or any other anneal (e.g., RTA).

The present invention ensures that the Boron is driven down the thicker polysilicon (e.g., over narrow moat widths) and also provides the necessary activation needed for achieving good inversion capacitance for higher drive current. The post-etch anneal may also be skipped and may be replaced with higher energy gate implants, which are activated during polysilicon re-oxidation and then later by S/D extension implant anneal and S/D implant anneal. Post etch anneal will generally be used because it does not impact the ability to collect ECD (electrical CD for gate CD control) data after the polysilicon gate etch. Also, since both transistor types (NMOS and PMOS) have gate dopants post gate etch, ECD data may be obtained, independently, for both, for better CD control.

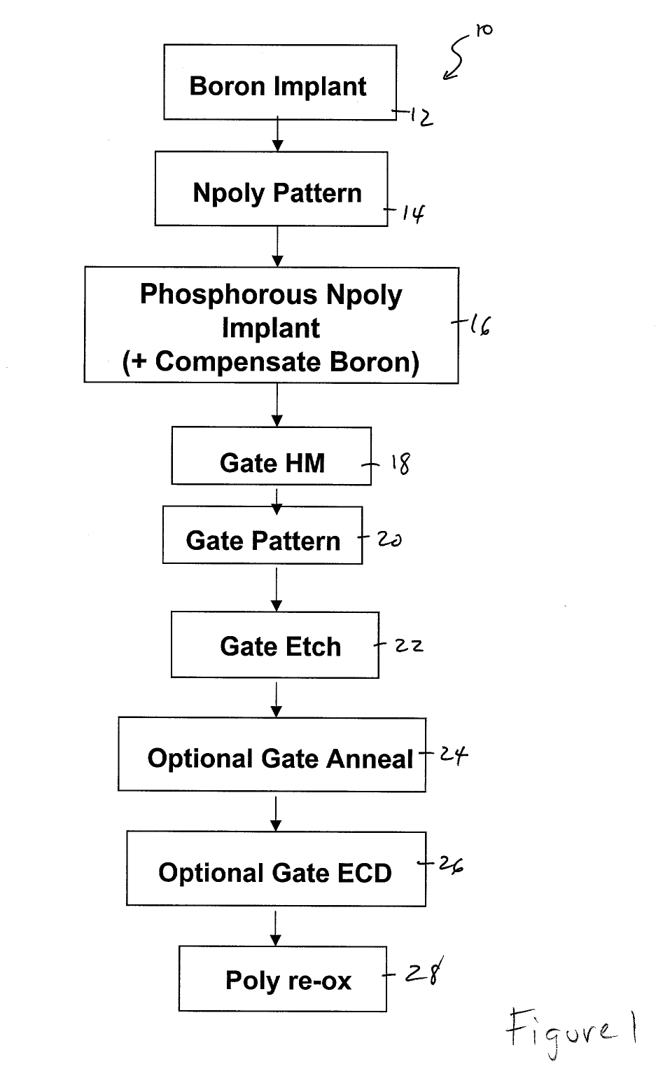

Referring now to FIG. 1, a method of the present invention is set forth in greater detail with reference to flowchart 10. Polysilicon that was blanket deposited on a gate oxide, grown or deposited on a substrate, is implanted with Boron in step 12. For example, the Boron may be ion implanted at an energy level of 5-15 keV and a dopant density of 5×10¹⁴ to 5×10¹⁵ atoms/cm². Next, in step 14 the regions of the polysilicon that are going to be implanted with N-type doping are patterned and the N-polysilicon is implanted in step 16. In certain cases it will be necessary to compensate for Boron in the N-polysilicon implantation step 16. Next, the polysilicon gate is prepared, patterned and etched (steps 18, 20 and 22). At this point two optional steps may be included for use with the present invention, namely, an optional gate anneal (step 24) and/or the electrical conductance determination for gate CD control (step 26). Finally, the entire wafer may subjected to thermal oxidation (step 28).

The substrate may be made of silicon, gallium arsenide, silicon on insulator (SOI) structures, epitaxial formations, germanium, germanium silicon, polysilicon, amorphous silicon, and/or like substrates, semi-conductive or conductive. The substrate is, however, typically made of single crystal silicon, and is usually lightly doped with Boron, Phosphorous or Arsenic atoms.

The silicon-containing material for a gate structure may be, e.g., polycrystalline silicon, epitaxial silicon or any other semiconducting material. The substrate may also include isolation structures between the regions for forming the different gate structures. These isolation structures may be, e.g., an oxide or some other insulator. The purpose of the isolation structure is to isolate the active devices from one another on the substrate. Once formed, the substrate may contain wells that will be of the opposite conductivity type when compared to the conductivity of the substrate.

A layer of silicon-containing material, which may be patterned and etched to form a gate structure, is formed on a standard gate dielectric. Gate dielectric may be made of an oxide, thermally grown SiO₂, a nitride, an oxynitride or any combination thereof, and is generally on the order of 1 to 10 nm thick. The gate structure on the gate dielectric may have sidewalls.

One advantage of the present invention is that the unannealed P and N implanted polysilicon etch very similarly during the gate etch. The similarity in etch rate is due to the fact that the dopants are not yet activated prior to the etch. Thus, the desired gate CD profile and gate CD control (NMOS vs PMOS) is easier to achieve using the present invention.

Due to higher energy pre-etch Boron implant, a spike anneal having a lower thermal budget is sufficient to result in high doping concentration at the poly/gate-oxide interface, thereby reducing polysilicon depletion. The Boron implant also helps reduce the edge polysilicon depletion for narrow polysilicon lines and larger polysilicon height. The method of the present invention does not involve any additional photolithography steps although an additional maskless implant is added. Furthermore, the polysilicon anneal may be skipped altogether, saving process cost and cycle time.

Although the invention has been described with reference to one or more embodiments, the description is not intended to be limiting, or construed in a limiting sense. Various modifications and combinations of the illustrative embodiment, as well as other embodiments of the invention, all of which are within the spirit and scope of the invention, will be apparent to persons skilled in the art upon reference to the description. For example, the process may be utilized in the fabrication of most devices. Similarly, the well or wells can be separately patterned and implanted at or near the beginning of the fabrication process.

What is claimed is:

1. A method of producing an integrated circuit comprising the steps of:
providing a semiconductor substrate;
forming a gate dielectric on an active area on the substrate;
depositing a polysilicon layer on top of the gate dielectric;
implanting Boron into the gate;
patterning an N-doped gate region;
implanting Phosphorous and Boron into the N-doped gate region;
patterning a gate; and
etching the gate.

2. The method of claim 1, further comprising the step of performing a gate anneal following the etching of the gate.

3. The method of claim 2, further comprising the step of performing an electrical critical dimension test on the gate following gate anneal.

4. The method of claim 1, wherein the gate comprises silicon.

5. The method of claim 1, further comprising the step of implanting the source/drain adjacent the gate.

6. The method of claim 1, further comprising the steps of:
patterning the P-doped gate;
implanting the P-doped gate;
patterning a gate; and
etching the gate.

7. A method of producing an integrated circuit with reduced gate depletion, comprising the steps of:
providing a semiconductor substrate;
forming a gate dielectric on the substrate;
depositing a gate layer on top of the gate dielectric;
implanting Boron into the gate;
patterning an N-doped gate;
implanting the N-doped gate with additional Boron;
implanting Phosphorous and Boron into the N-doped gate region;
etching the gate;
performing a gate anneal; and
conducting a thermal oxidation.

8. The method of claim 7, further comprising the steps of:
patterning a P-doped gate;
implanting the P-doped gate;
patterning a gate; and
etching the gate.

9. The method of claim 7, further comprising the step of performing an electrical critical dimension test on the gate following gate anneal.

10. The method of claim 7, wherein the gate comprises silicon.

11. The method of claim 7, wherein the thermal oxidation comprises a rapid thermal oxidation.

12. The method of claim 7, further comprising the step of implanting a source/drain adjacent the gate.

13. The method of claim 7, wherein the N-doped gate is implanted with additional Phosphorous to compensate for the presence of Boron in the N-doped gate.

14. A method of producing an integrated circuit, comprising the steps of:
providing a semiconductor substrate;
forming a gate dielectric on the substrate;
depositing a gate layer on top of the gate dielectric;
implanting Boron into the gate;
patterning an N-doped gate;
implanting the N-doped gate with Phosphorous and Boron;
patterning a gate; and
etching the gate.

15. The method of claim 14, wherein the thermal oxidation is a spike anneal.

16. The method of claim 14, wherein the gate comprises silicon.

17. The method of claim 14, further comprising the step of implanting a source/drain adjacent the gate.

18. The method of claim 14, further comprising the steps of:
patterning a P-doped gate;
implanting the P-doped gate;
patterning a gate; and
etching the gate.
